(19) United States
(12) Patent Application Publication
(10) Pub. No.: US 2002/0113317 A1
(43) Pub. Date: Aug. 22, 2002

(54) A SEMICONDUCTOR DEVICE HAVING HYDOGEN DIFFUSION AND BARRIER LAYERS AND A METHOD OF PRODUCING THE SAME

(75) Inventor: Mototsugu Okushima, Tokyo (JP)

Correspondence Address: Scully, Scott, Murphy & Presser, 400 Garden City Plaza, Garden City, NY, 11530, US

(73) Assignee: NEC CORPORATION, TOKYO (JP)

(21) Appl. No.: 10/119,800

(22) Filed: Apr. 10, 2002

Related U.S. Application Data
(62) Division of application No. 09/470,396, filed on Dec. 22, 1999, now abandoned.

(30) Foreign Application Priority Data
Jan. 12, 1999 (JP) 5535/1999

(51) Int. Cl. H01L 23/48

(52) U.S. Cl. 257/774

(57) ABSTRACT

An object of the present invention is to provide a semiconductor device having a buried metal wiring structure and a contact structure passing through a film having hydrogen barrier function for electrically connecting respective wiring layers each other and further having a hydrogen diffusing passage allowing hydrogen to reach an interior of the semiconductor device so that an annealing can be performed effectively by using a forming gas and a fabrication method thereof. The hydrogen diffusing passage is provided by providing an opening in a portion of a layer other than a portion thereof immediately below the metal wiring and allows hydrogen to pass the opening to lower layers.

### BACKGROUND OF THE INVENTION

1. Field of the Invention

The present invention relates to a semiconductor device having a contact structure for electrically connecting respective layers of the semiconductor device to a buried metal wiring structure thereof and, particularly, the present invention relates to a semiconductor device with which an effect of an annealing processing of a semiconductor device performed in a final step of a fabrication method of the semiconductor device with using a forming gas is improved.

2. Description of the Related Art

In order to stabilize electric characteristics of a semiconductor device, an annealing processing has been performed in a forming gas environment. The forming gas is a mixture gas containing hydrogen. By the annealing processing performed in the forming gas environment, hydrogen atoms are introduced into an interface between a silicon substrate of the semiconductor device and a gate oxide film formed on the substrate and an interface between a source.drain diffusion layer and the silicon substrate underlying the source.drain diffusion layer. As a result, dangling bond, which is junction defect of silicon-oxygen, disappears and/or fixed charge in the gate oxide film is neutralized.

In a case where a multi-layered wiring is formed on an LSI by utilizing a self-alignment type process, it is necessary to form an etch stop film exemplified by a silicon nitride film on an element forming region of the LSI. Since the etch stop film forms a hydrogen diffusion barrier, hydrogen atoms do not reach the interface between the gate oxide film and the silicon substrate and the interface between the source-drain diffusion layer and the silicon substrate underlying the source drain diffusion layer. Therefore, it is impossible to effectively perform the annealing processing with using the forming gas.

FIG. 1 is a cross section of a conventional semiconductor device having a buried metal wiring structure and a contact structure for electrically connecting between respective wiring layers of the buried metal wiring structure, which is disclosed in Japanese Patent Application Laid-open No. H9-20942.

The semiconductor device having such structure is formed by damascene method or dual-damascene method.

In FIG. 1, the semiconductor device has two metal wiring layers connected to semiconductor elements. Semiconductor elements 1005 are formed on a semiconductor substrate 1001 and are connected to a metal wiring layer 1004a through contact plugs 1003a and the metal wiring layer 1004a is connected to a metal wiring layer 1004b through contact plugs 1003b.

Etch stop films 1002a are formed beneath the metal wiring layers 1004a and 1004b, respectively, and an etch stop film 1002b is formed below the contact plugs 1003b. That is, the etch stop film 1002a underlying the metal wiring layer functions as an etch stop film in forming wiring grooves in an interlayer insulating film 1006a and the etch stop film 1002b underlying the contact plugs functions as an etch stop film in forming contact holes in an interlayer insulating film 1006b.

In order to distinguish between these etch stop films, the etch stop film immediately below the metal wiring layer (1002a in FIG. 1) will be referred to as a metal wiring etch stop film and the etch stop film immediately below the contact plugs (1002b in FIG. 1) will be referred to as a contact plug etch stop film.

The etch stop films 1002a and 1002b are usually nitride films formed of SiON or Si₃N₄. It has been known that, when the nitride film is thin, hydrogen tends to permeate the nitride film, while its etch stop function is degraded. On the other hand, when the nitride film is thick, its permeability and diffusivity for hydrogen are degraded while the etch stop function is improved. Therefore, in order to maintain a required etch stop function, the nitride film is made as thick as 500 Å. In such case, however, hydrogen does not reach an interface between the gate oxide film and the silicon substrate and an interface between a source.drain diffusion layer and the silicon substrate immediately below the source.drain diffusion layer, so that it is impossible to obtain a practical annealing effect.

With the existence of the etch stop films 1002a and 1002b having the hydrogen barrier function in any layers of the semiconductor device, hydrogen diffusing from the upper layer 1004b in the annealing step is blocked by the etch stop films 1002a and 1002b since the latter films cover a whole surface of the semiconductor device when looked totally as shown in FIG. 1, so that it is impossible to perform the effective annealing.

The problem of the hydrogen barrier effect of the metal wiring etch stop film 1002a underlying the metal wiring layer and the contact plug etch stop film 1002b underlying the contact plugs of the multi-layered metal wiring thus formed on the semiconductor substrate was described.

As another example, there is a case where a nitride film is formed to cover an element structure formed in the lowermost layer of a semiconductor device.

FIG. 2 shows a MOS FET structure formed on a semiconductor substrate 1101, which is disclosed in Japanese Patent Application Laid-open No. H10-20964. A source 1102 and a drain 1103 are formed in an element forming region of the semiconductor substrate 1101 isolated by an element isolation film 1104 on the semiconductor substrate. Further, a gate electrode 1106 is formed in the element forming region of the semiconductor substrate through a gate insulating film 1105. On a side wall of the gate electrode 1106, a sidewall 1107 is formed. In order to reduce a contact resistance with contact plugs 1111, a silicide film 1108 may be formed on the source.drain region.

An insulating film 1110 is formed on these elements and the contact plugs 1111 are formed through the insulating film 1110. Through the contact plugs 1111, the source 1102, the drain 1103 or the gate electrode 1106 is electrically connected to an upper layer (not shown) formed on the insulating film 1110.

In such MOS FET structure, a nitride film 1109 functioning as an etch stop film for forming the contact plugs 1111 becomes necessary. When the etch stop film is a Si₃N₄ film, the etch stop film is usually formed to a thickness of 500 Å.

In such case, however, hydrogen atoms do not reach the interface between the gate oxide film and the silicon substrate and the interface between the source.drain diffusion layer and the silicon substrate underlying the source.drain diffusion layer, so that it is impossible to obtain a practically effective annealing effect.

FIGS. 3a to 3d show a fabrication steps of another conventional semiconductor device having a structure fabricated according to a technique disclosed in U.S. Pat. No. 5,736,457. As shown in FIG. 3a, a metal layer 100 is formed on a semiconductor substrate 101 and a first insulating film 105 is formed on a whole surface of the semiconductor substrate including the metal layer 100. An etch stop layer 110 of an electrically conductive material such as Al—Cu, Ti, TiN or TiW is formed on the first insulating film 105 and patterned as shown. A second insulating film 120 is formed on the first insulating film 105 and the etch stop layer 110 and then a reverse conductor pattern 130 is formed as a photo resist on the second insulating film 120, as shown in FIG. 3B. A width of an opening of the photo resist pattern 130 is slightly smaller than a width of the etch stop layer 110 formed beneath the photo resist pattern 130.

Thereafter, as shown in FIG. 3C, the first insulating film 105 and the second insulating film 120 are etched with using the photo resist pattern 130 and the etch stop layer 110 as a mask. After the photo resist pattern 130 is removed, a wiring 150 is provided in a via-hole 140 and on the etch stop layer 110 and then the second insulating film 120 is exposed by etching the wiring 150 back, as shown in FIG. 3D.

According to this fabrication method, the position and the shape of the via-hole 140 formed in the first insulating film 105 is determined by the shape of the etch stop layer 110 and the shape of the opening of the photo resist pattern 130. That is, since the position and the shape of the via-hole 140 are determined by the two exposure steps, it is very difficult to form the via-hole 140 having the predetermined shape in the predetermined position when the position of the mask used in the second exposure deviates from that of the first exposure.

### SUMMARY OF THE INVENTION

The present invention was made in view of the state of art and an object of the present invention is to provide, in order to perform an effective annealing of a semiconductor device, a countermeasure against the problem of hydrogen blocking function of an etch stop film, etc., formed in an upper layer portion of the semiconductor device.

Another object of the present invention is to provide a countermeasure against the problem of hydrogen blocking function of a nitride film covering semiconductor elements formed on a semiconductor substrate.

A further object of the present invention is to provide a semiconductor device having a contact structure for electrically connecting a buried metal wiring structure to respective buried metal wiring layers and a film having hydrogen barrier function, which is capable of being effectively annealed by using a forming gas, and a fabrication method of the same semiconductor device. One of features of the present invention is a provision of a hydrogen diffusing passage capable of guiding hydrogen to an interior of a semiconductor device having a contact structure for electrically connecting a buried metal wiring structure to respective buried metal wiring layers and a film having hydrogen barrier function.

In order to achieve the above objects, a semiconductor device according to the present invention, which includes a first insulating film for covering semiconductor elements or a wiring, which are formed on a semiconductor substrate, at least one contact plug passing through the first insulating film and electrically connected to the semiconductor elements or the wiring, a second insulating film formed on the first insulating film and a metal wiring buried in the second insulating film and electrically connected to the contact plugs, is featured by further including a film having hydrogen barrier function and formed in at least immediately below the metal wiring and between the metal wiring and the first insulating film, the film having hydrogen barrier function being formed with an opening in other portion thereof than the portion immediately below the metal wiring and between the metal wiring and the first insulating film to provide a hydrogen diffusing passage to layers of the semiconductor device formed below the second insulating film.

According to another aspect of the present invention, a semiconductor device, which comprises a second insulating film formed on a first insulating film, which buries a metal wiring, and at least one contact plug passing through the second insulating film and electrically connected to the wiring, is featured by that the metal wiring is formed in the first insulating film and having an upper surface lower than an upper surface of the first insulating film to form a space above the upper surface of the metal wiring, a film having etch stop function is formed in only the space to bury the metal wiring in the first insulating film and, when the film having etch stop function is an electrically non-conductive film, the contact plug passes through the film having etch stop function and is electrically connected to the metal wiring or, when the film having etch stop function is an electrically conductive film, the contact plug is electrically connected to the metal wiring through the film having etch stop function and a hydrogen diffusing passage extending downwardly of the second insulating film is provided through other area than an area on which the metal wiring is formed.

According to another aspect of the present invention, a semiconductor device, which includes a second insulating film formed on a first insulating film burying a metal wiring and at least one contact plug passing through the second insulating film and electrically connected to the metal wiring, is featured by further including a film having etch stop function and formed between the second insulating film and the metal wiring, wherein, when the film having etch stop function is an electrically non-conductive film, the contact plug passes through the film having etch stop function and is electrically connected to the metal wiring and, when the film having etch stop function is an electrically conductive film, the contact plug is electrically connected to the metal wiring through the film having etch stop function and wherein the film having etch stop function is removed except a portion thereof formed in the vicinity of connecting portions between the contact plug and the metal wiring to provide a hydrogen diffusing passage extending downwardly of the second insulating film.

According to a further aspect of the present invention, a semiconductor device, which includes at least a semiconductor element formed on a semiconductor substrate, an insulating film covering said semiconductor element and at least one contact plug passing through the insulating film and electrically connected to at least one electrode of the semiconductor element, is featured by further including a silicide film formed on a surface of the electrode and a Si₃N₄ film having thickness in a range from 50 Å to 100 Å and formed between the silicide film and the insulating film, wherein the contact plug passes through the Si₃N₄ film and is electrically connected to the silicide film.

According to another aspect of the present invention, a fabrication method for fabricating a semiconductor device including a first insulating film covering at least one semiconductor or a wiring formed on a semiconductor substrate, at least one contact plug passing through the first insulating film and electrically connected to the semiconductor element or the wiring, a second insulating film formed on the first insulating film and a metal wiring buried in the second insulating film and electrically connected to the contact plug is provided. The fabrication method comprises the steps of (a) forming a film having hydrogen barrier function on the first insulating film, (b) patterning the film having hydrogen barrier function to form at least one via-hole for forming at least one contact hole and an opening functioning as a hydrogen diffusing passage in the film having hydrogen barrier function, while leaving a portion of the film having hydrogen barrier function as an etch stop film functioning in forming said metal wiring, (c) forming a second insulating film on the patterned film having hydrogen barrier function on the first insulating film, (d) forming, on the second insulating film, a resist pattern for forming wiring grooves for the metal wiring, (e) simultaneously forming the wiring grooves and the contact hole by simultaneously etching the first and second insulating films with using the resist pattern as a mask, the film having hydrogen barrier function as an etch stop film for the wiring grooves and the via-hole as a mask opening of the contact hole and (f) forming the contact plug by filling the wiring grooves and the contact hole with a metal material after the resist film is removed.

According to a still further aspect of the present invention, a fabrication method for fabricating a semiconductor device including a second insulating film formed on a first insulating film burying a metal wiring and at least one contact plug passing through the said second insulating film and electrically connected to the metal wiring is provided. The fabrication method comprises the steps of (a) selectively etching the metal wiring buried in the first insulating film to remove an upper portion of the metal wiring in the first insulating film to provide a space on a selectively etched portion of the metal wiring, (b) forming a film having etch stop function in only the space on the metal wiring, (c) forming a second insulating film on the film having etch stop function on the first insulating film and (d) forming the contact plug such that the contact plug passes through the second insulating film and the film having etch stop function and is connected to the metal wiring, when the film having etch stop function is an electrically non-conductive film, or forming the contact plug such that the contact plug passes through the second insulating film and is electrically connected to the metal wiring through the film having etch stop function, when the film having etch stop function is an electrically conductive film.

### BRIEF DESCRIPTION OF THE DRAWINGS

The above and other objects, advantages and features of the present invention will become more apparent from the following description taken in conjunction with the accompanying drawings, in which:

FIG. 1 is a cross section showing a conventional semiconductor device having a buried metal wiring structure and a contact structure for electrically connecting layers each other;

FIG. 2 is a cross section showing a conventional MOS FET structure formed on a semiconductor substrate;

FIGS. 3a to 3d are perspective views showing fabrication steps of a conventional semiconductor device having a buried metal wiring structure and a contact structure for electrically connecting layers each other;

FIGS. 4a and 4b are a cross sectional view and a plan view of a layer construction of a semiconductor device having a hydrogen diffusing route according to a first modification of a first embodiment of the present invention;

FIGS. 5a and 5b are a cross sectional view and a plan view of a layer construction of a semiconductor device having a hydrogen diffusing route according to a second modification of the first embodiment of the present invention;

FIGS. 6a to 6d are cross sections showing fabrication steps of a fabrication method of a semiconductor device having the hydrogen diffusing route of the first embodiment of the present invention;

FIGS. 7a to 7g are cross sections showing fabrication steps of a semiconductor device having an etch stop film underlying contact plugs formed on only a metal wiring, according to a first modification of a second embodiment of the present invention;

FIGS. 8a to 8f are cross sections showing fabrication steps of a semiconductor device having an etch stop film underlying contact plugs formed on at least a metal wiring, according to a second modification of the second embodiment of the present invention;

FIG. 9 is a cross section showing a MOS FET type transistor structure, in which hydrogen can reach an interior of a gate electrode, according to a third embodiment of the present invention;

FIG. 10 is a graph showing a relation between thickness of Si₃N₄ film and interface level recovery rate; and

FIG. 11 shows a semiconductor device, which can be effectively annealed by using forming gas, according to a fourth embodiment of the present invention.

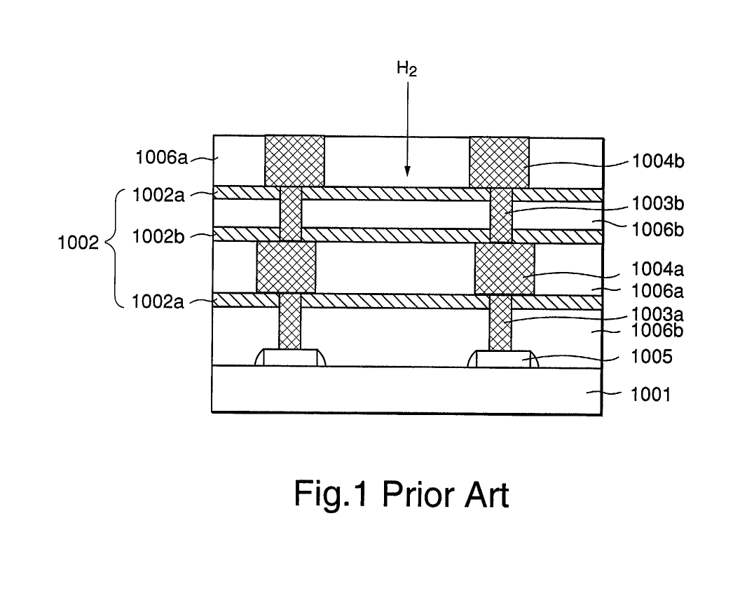

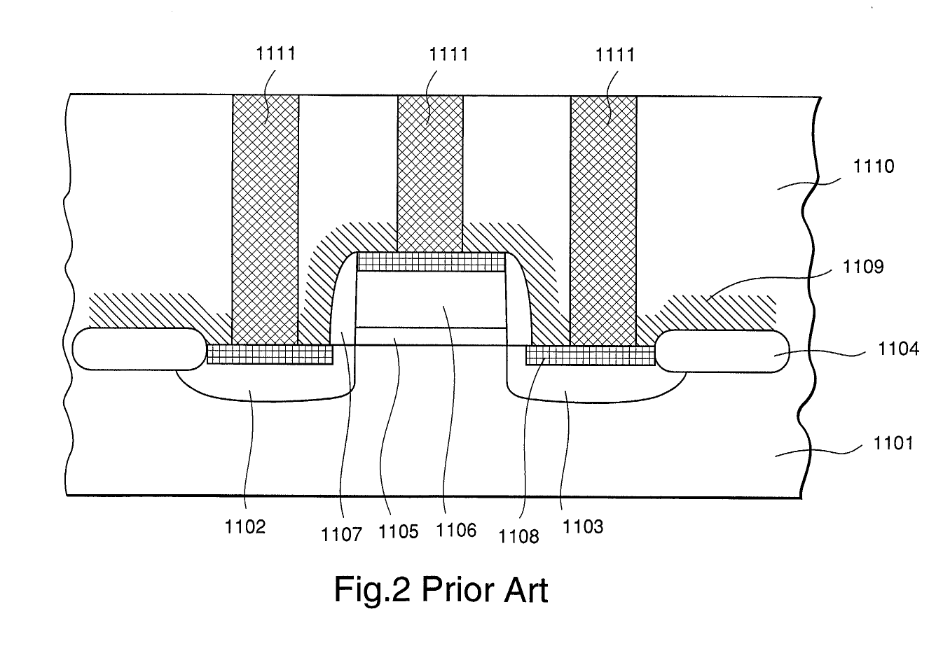

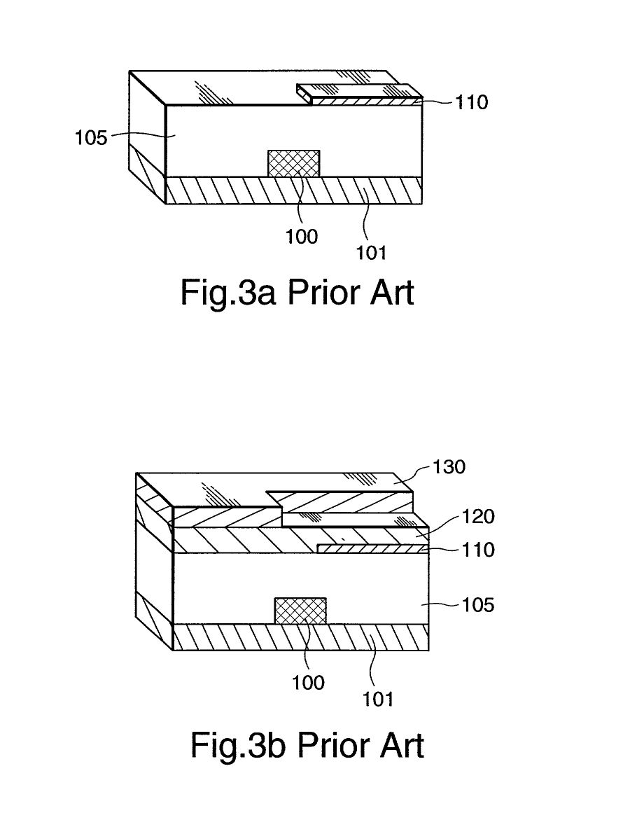

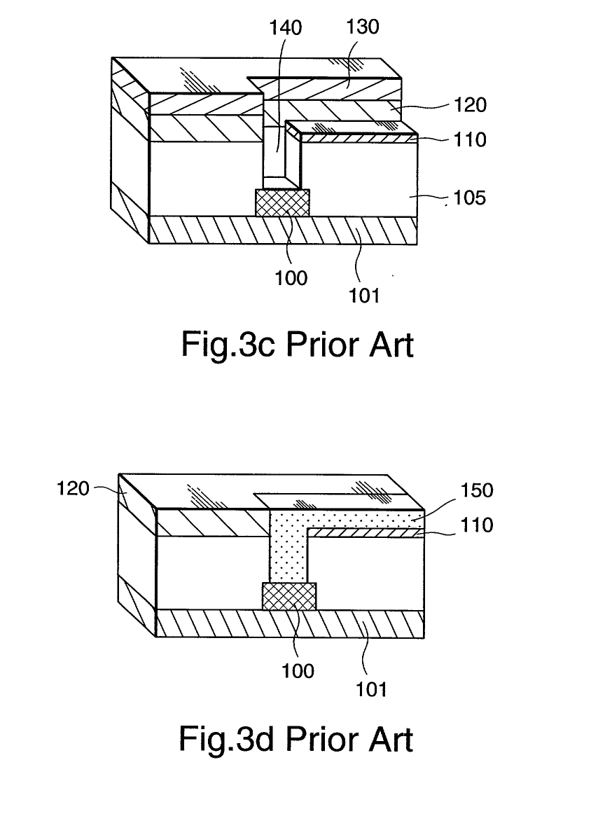

### DETAILED DESCRIPTION OF THE PREFERRED EMBODIMENTS

Embodiments of the present invention will be described with reference to the drawings.

<First Embodiment>

A structure of a semiconductor device having an etch stop film underlying a metal wiring, formed with an opening functioning as a hydrogen diffusing passage, and a fabrication method thereof will be described first.

(First Modification of the First Embodiment)

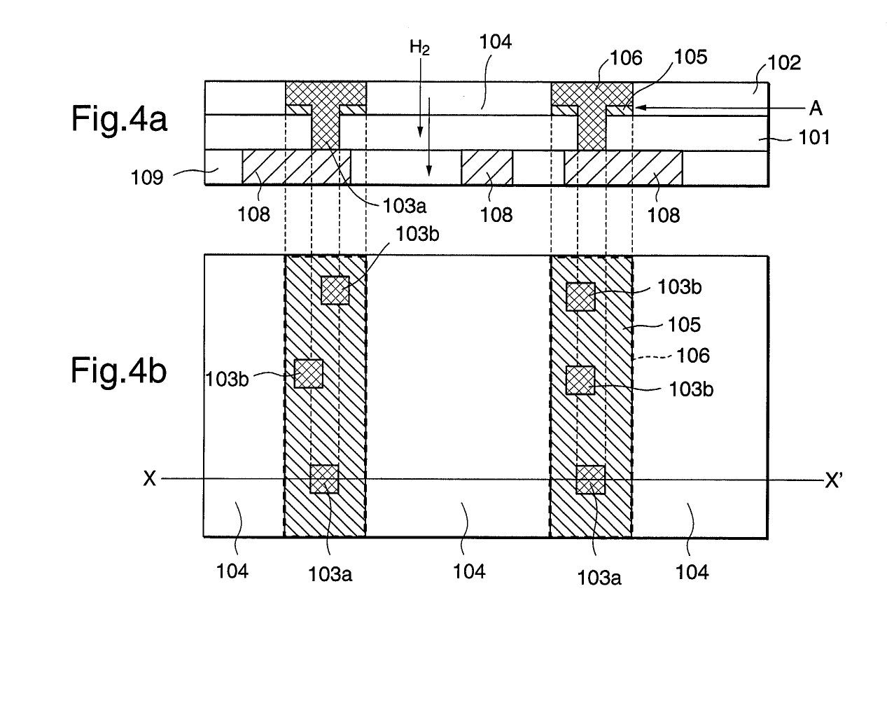

FIG. 4a is a cross section of the semiconductor device having the hydrogen diffusing passage according to the first modification of the first embodiment, taken along a line X-X′ in FIG. 4b, which is a plan view thereof. As shown in FIG. 4a, a layer 108 including semiconductor elements or wiring, which will be referred to as totally “lower wiring layer”, hereinafter, and an insulating layer 109 are formed on a semiconductor substrate (not shown). Another insulating layer 101 is formed on the lower wiring layer 108 and the insulating film layer 109.

The lower wiring 108 may include semiconductor elements or wiring, formed on the semiconductor substrate. The semiconductor elements formed on the semiconductor substrate may be a MOS transistor or transistors and/or a bipolar transistor or transistors, etc. Wiring formed on the semiconductor substrate means a wiring formed on the semiconductor element or elements through an insulating film and, in a case where a semiconductor device has a multi-layer wiring structure, any of wiring layers thereof. The wiring may be a buried metal wiring such as a usual aliminum wiring or a copper damascene wiring.

As shown in FIG. 4a, the first insulating film 101 is formed on the lower wiring layer 108 and the insulating film 109. Further, a metal wiring etch stop film 105 underlying the metal wiring is formed on the first insulating film 101. The metal wiring etch stop film 105 has hydrogen barrier function. Further, a second insulating film 102 is formed on an area of the first insulating film 101, on which the metal wiring etch stop film 105 is not formed. A metal wiring 106 is buried in the second insulating film 102. The metal wiring 106 and the lower wiring layer 108 are electrically connected each other by contact plugs 103a formed in the first insulating film 101.

FIG. 4b is a plan view of the semiconductor device shown in FIG. 4a when looked in a plane indicated by an arrow A in FIG. 4a. The metal wiring 106 is shown by a dotted line since it is in a layer above the plane indicated by the arrow A.

As shown in FIG. 4b, the films 105 having hydrogen barrier function, which blocks permeation of hydrogen, are formed on only areas of the first insulating film 101 immediately below the metal wiring 106 except a region of the contact plugs 103 and openings 104 are formed in the remaining region of the first insulating film 101.

The contact plugs 103b are electrically connected the lower wiring layer 108 to the metal wiring 106 in locations other than that shown in FIG. 4a. The lower wiring layer 108, to which the contact plug 103b is connected, may be the same lower wiring 108, to which the contact plugs 103a are connected or any other lower wiring layer 108 provided in the same layer as that of the lower wiring layer 108, to which the contact plugs 103a are connected.

In a recent semiconductor device, contact plugs such as the contact plugs 103b are provided in addition to contact plugs such as the contact plugs 103a in order to electrically connect the metal wiring 106 to the lower wiring layer 108 reliably. In order to provide a plurality of contact plugs 103a and 103b, the size of the contact plugs 103a and 103b is made smaller than a width of the metal wiring 106.

Further, it is usually requested to electrically connect the metal wiring 106 to a plurality of different lower wiring layers 108. In such case, the contact plugs 103b each having a size smaller than the width of the metal wiring 106 are provided.

The film 105 having hydrogen barrier function is used as an etch stop film in forming wiring grooves in the second insulating film 102 in a metal wiring forming step.

According to the present invention, the film 105 having hydrogen barrier function is formed on at least the region of the first insulating film 101 immediately below the metal wiring 106, so that the hydrogen barrier film 105 functions as the etch stop film in forming the metal wiring 106 by etching grooves in the second insulating film 102. The opening 104 is formed in the remaining region of the film 105 having hydrogen barrier function to provide the hydrogen diffusing passage to the lower layers below the second insulating film 102 during the annealing operation.

(Second Modification of the First Embodiment)

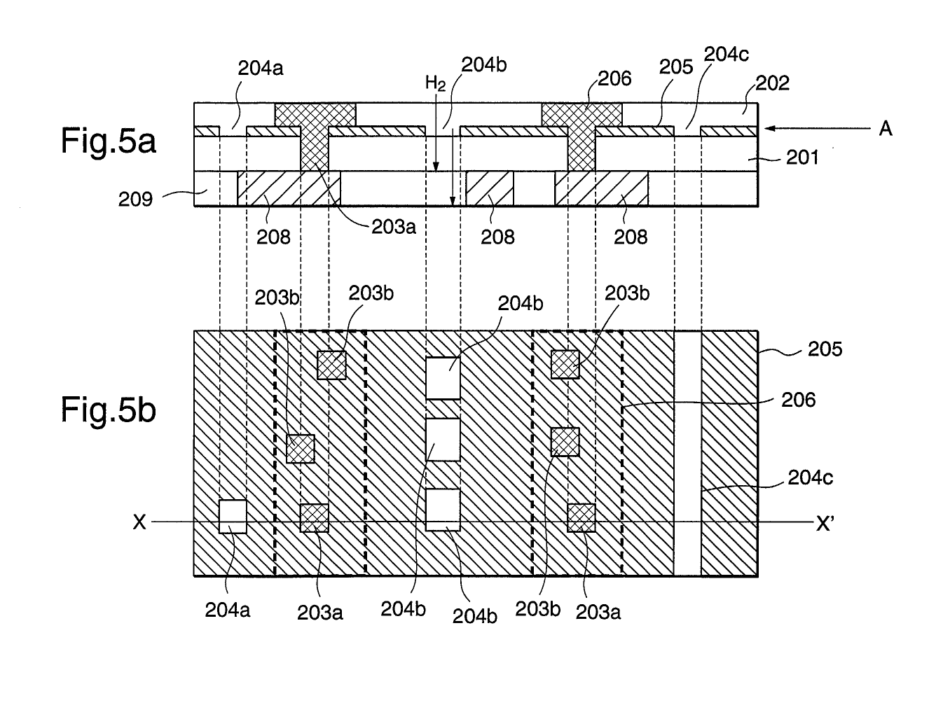

FIG. 5a is a cross section of the semiconductor device having the hydrogen diffusing passage according to the second modification of the first embodiment, taken along a line X-X′ in FIG. 5b, which is a plan view thereof.

As shown in FIG. 5a, a first insulating film 201 is formed on a lower wiring layer 208 and an insulating film 209. Further, a metal wiring etch stop film 205 is formed on the first insulating film 201. The metal wiring etch stop film 205 has hydrogen barrier function. Further, a second insulating film 202 is formed on the first insulating film 201 and the metal wiring etch stop film 205. A metal wiring 206 is buried in the second insulating film 202. The metal wiring 206 and the lower wiring layer 208 are electrically connected each other through contact plugs 203a formed in the first insulating film 201.

The contact plugs 203b electrically connect the lower wiring layer 208 directly to the metal wiring 206 in locations other than that shown in FIG. 5a. The lower wiring layer 208, to which the contact plugs 203b are electrically connected, may be the same as the lower wiring layer 208, to which the contact plugs 203a are connected or any other lower wiring layer 208 provided in the same layer as that of the lower wiring layer 208, to which the contact plugs 203a are connected.

As shown in FIGS., 5a and 5b, an opening is formed in a portion of the film 205 having hydrogen barrier function.

It is possible to form a discrete opening such as the opening 204a, to equidistantly form a plurality of openings such as openings 204b or to form slit-like openings such as openings 204c.

There is no specific limitation in the size, etc., of the opening. However, since, under usual annealing condition and when the first insulating film 201 is a silicon oxide film, diffusion length of hydrogen is about 100 μm, it is possible to suitably determine a location, size and shape of the opening such that the opening is located within a range of distance of about 100 μm from a semiconductor element formed on the semiconductor substrate.

In the structure shown in FIGS. 4 or 5, the film having hydrogen barrier function means a film, which does not allow substantial diffusion of hydrogen. For example, the film having hydrogen barrier function may be a nitride film such as SiON film or Si₃N₄ film, which is usually used as the etch stop film in forming the metal wiring. This is also true for a film having hydrogen barrier function to be described later.

The insulating film is a film such as usually used BPSG film, PSG film, SOG film, HSQ (Hydrogen Silisesquioxane) film, SiO₂ film or SiOF film, which substantially diffuse hydrogen. This is also true for insulating films to be described later.

The metal wiring may be prepared by burying copper, copper alloy, tungsten or aluminum in the wiring grooves. A bottom and side surface of such buried metal may be coated by a barrier metal such as Ta, TaN, WN or TiN, etc. This is also true for metal wiring to be described later.

The contact plug is of tungsten, copper, copper alloy or aluminum, etc., and a bottom and side surface of the contact plug may be coated by Ti/TiN film. This is also true for contact plugs to be described later.

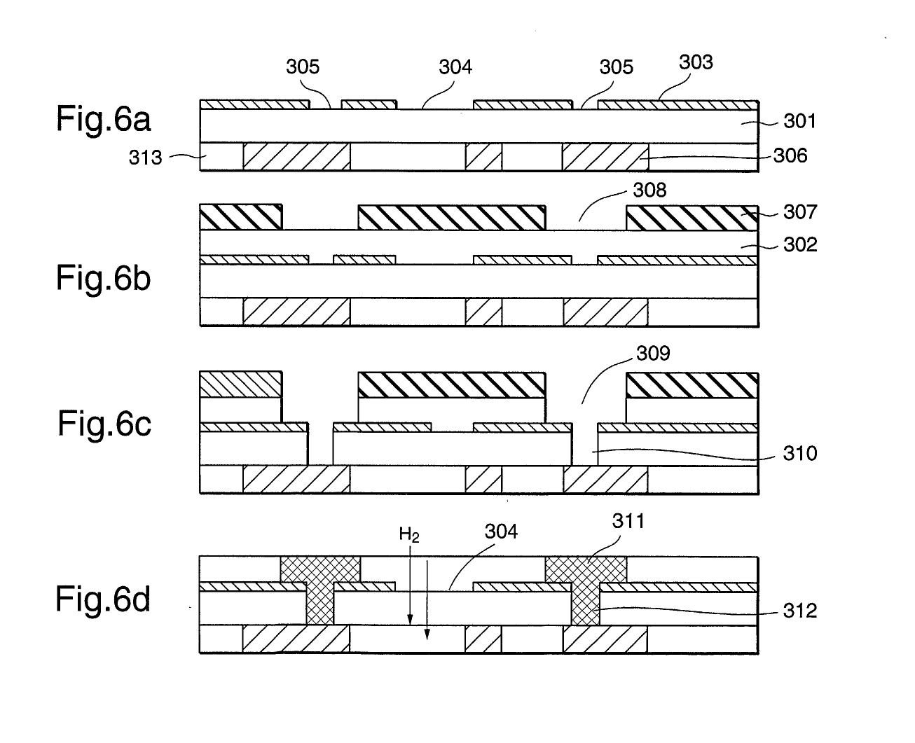

A fabrication method of the semiconductor device having the above mentioned structure will be described with reference to FIGS. 6a to 6d, which are cross sections showing fabrication steps of the semiconductor device having the hydrogen diffusing route shown in FIG. 5.

As shown in FIG. 6a, a first insulating film 301 is formed on a lower wiring 306 and an insulating film 313 and then a film 303 having hydrogen barrier function is formed on the first insulating film 301. The film 303 functions as an etch stop film in the subsequent steps. Further, the film 303 having hydrogen barrier function is patterned to form an opening 304 and openings 305. Each of the openings 305 is formed in a location, at which a contact hole extending up to the lower wiring 306 is to be formed in the first insulating film 301. The opening 304 provides the hydrogen diffusing passage. In this case, it is necessary to leave the opening 304 in a region, which functions as the etch stop film in forming wiring grooves 309 in the second insulating film 302.

Subsequently, as shown in FIG. 6b, the second insulating film 302 is formed on the first insulating film 301 through the hydrogen barrier film 303 and then a resist film 307 is formed thereon. Resist openings 308 patterned correspondingly to the wiring groove to be formed in the second insulating film 302 are formed in the resist film 307.

Thereafter, as shown in FIG. 6c, the first insulating film 301 is etched away by using the resist film 307 as a mask. In this case, the hydrogen barrier film 303 functions as an etch stop film for the wiring groove 309. Simultaneously therewith, contact holes 310 are formed by etching the second insulating film 302 with using the hydrogen barrier film 303 as a mask. In this manner, both the wiring grooves and the contact holes are formed simultaneously in one step.

Thereafter, as shown in FIG. 6d, the resist film 307 is removed and, then, the wiring groove 309 and the contact holes 301 are filled with a metal material 311. Then, an excessive metal material on the second insulating film 302 is removed by such as CMP method, etc., resulting in contact plugs 312 connecting between the metal wiring 311 and the lower layers. As shown in FIG. 6d, the hydrogen diffusing passage is provided by the opening 304.

The size and shape of the opening 304 formed in the step shown in FIG. 6a may be selected suitably according to a circuit design and a structure of the semiconductor device.

However, the size and shape of the hydrogen barrier film 303 must be selected such that it can function as an etch stop film in forming the second insulating film 309 in the step shown in FIG. 6c. In forming the wiring grooves 309, a portion of the hydrogen barrier film 303, which is exposed in the bottom of the wiring grooves 309, is important in the process and so the opening 304 can not be enlarged up to that portion. That is, even if the opening 304 is to be expanded maximally, the hydrogen barrier film 303 is left on the region immediately below the metal wiring 311.

Further, it is preferable, in order to make the etching speed of the hydrogen barrier film 303 in the opening portion 304 substantially equal to that in the openings 305, to make the size of the opening 304 substantially the same as that of the opening 305. For example, when the size of the opening 305 is in a range from 0.2 μm×0.2 μm to 0.5 μm×0.5 μm, the size of the opening 304 is made equal to the size of the opening pattern 305.

In the first modification of the first embodiment, shown in FIGS. 4a and 4b, the opening 104 having the size larger than that of the opening for the contact plug 103a or 103b is provided in the hydrogen barrier film 105 as the hydrogen diffusing passage. In forming these openings in the hydrogen barrier film 105 by etching, there may be a case where the etching speed of the openings for the contact plugs 103a and 103b is lower than that of the opening 104 as the hydrogen diffusing passage, so that it becomes impossible to form the opening 104 reliably. As a result of this problem, the hydrogen barrier film 105 left non-etched becomes a mask in the subsequent etching step of the first insulating film 101 and the second insulating film 102, so that it may become impossible to etch the first insulating film 101 and the formation of the contact holes 103a and the connection of the metal wiring 106 to the lower wiring 108 may become unsatisfactory.

However, according to the second modification, it is possible to make the etching speed of the film 205 having hydrogen barrier function for forming the openings 204a, 204b and 204c substantially the same as that of the film 205 having hydrogen barrier function for forming the contact plugs 203a and 203b by making the size of the openings 204a, 204b and 204c close or substantially equal to the size of the openings for forming the contact plugs 203a and 203b. Consequently, it is possible to reliably form these openings to thereby solve the problem of degradation of the formation of the contact plugs 203a and 203b and the problem of defective connection of the metal wiring 206 to the lower wiring layer 208.

Further, in the first modification of the first embodiment, the resist opening 308 must be precisely registered with the patterned film 303 having hydrogen barrier function. That is, if the resist opening 308 is not precisely registered with the patterned film 303 having hydrogen barrier function, the first insulating film 301 will be over-etched at the location of the non-registered portion. If an opening formed by the over-etching reaches unexpected portion of the lower wiring layer 306 other than portions of the lower wiring 306 to be connected to the wiring 311, the unexpected lower wiring layer will be electrically connected to the wiring 311 after the step for filling the opening with metal.

According to the second modification of the first embodiment, however, the above problems do not occur even when the resist opening 308 is not exactly registered with the patterned film having hydrogen barrier function.

<Second Embodiment>

A semiconductor device having an opening formed in an under-contact plug etch stop film functioning as a hydrogen diffusing passage and a method for fabricating the same will be described.

(First Modification of the Second Embodiment)

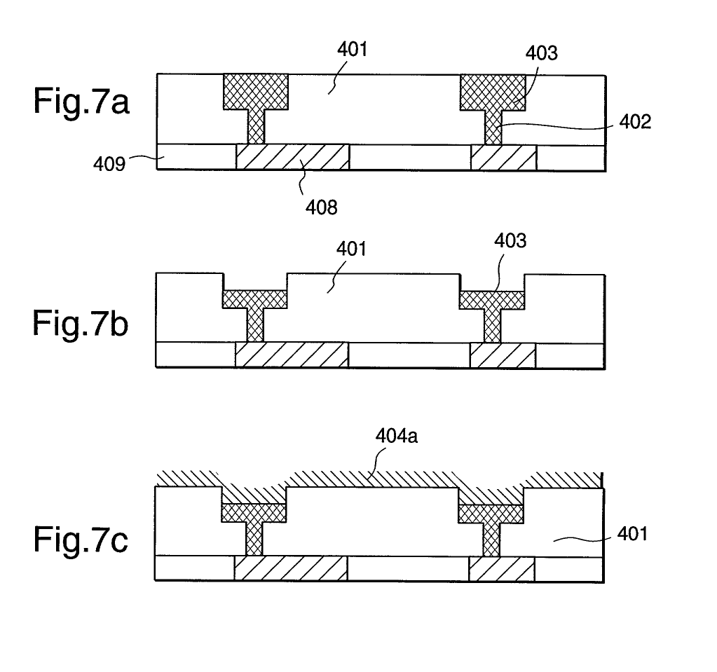

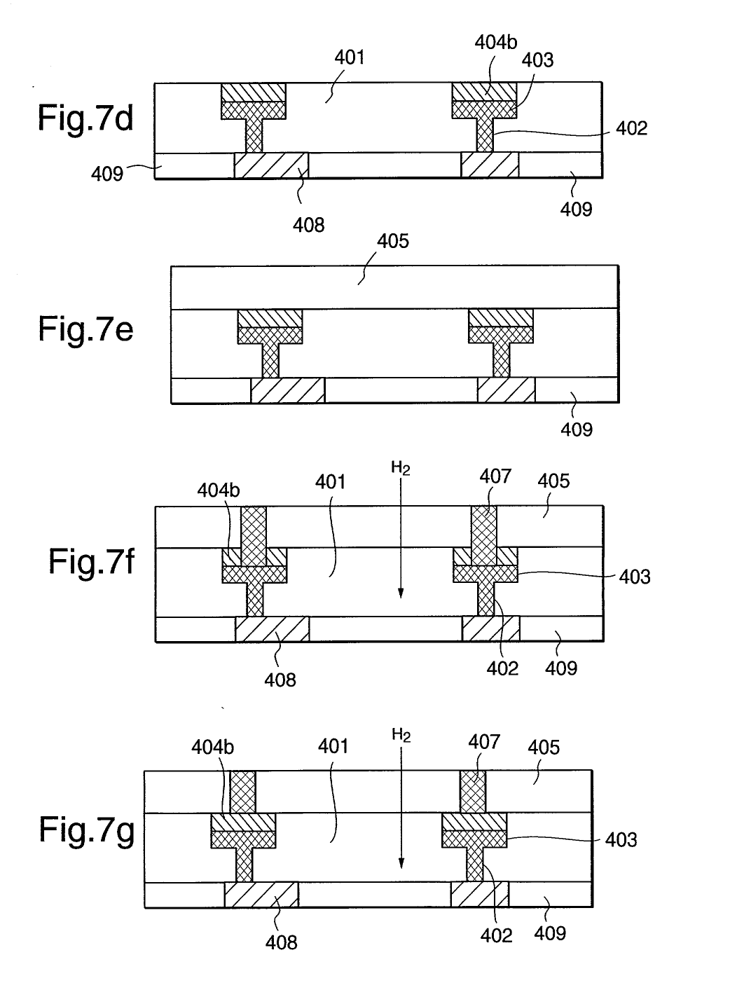

FIGS. 7a to 7g are cross sections showing fabrication steps of a semiconductor device having an under-contact plug etch stop film underlying contact plugs and formed with an opening. In the first modification of the second embodiment, the under-contact plug etch stop film is formed on only a metal wiring.

In FIG. 7a, metal wiring layers 403 are formed by burying a metal in an insulating film 401 and are electrically connected to a lower wiring 408 through contact plugs 402. A reference numeral 409 depicts an insulating film.

The metal wiring layers 403 are partially removed from an upper surface of the insulating film 401, as shown in FIG. 7b, by etching the metal with using an etchant having high selective etching rate for the metal.

For example, when the metal used for the metal wiring 403 is copper or copper alloy, the partial removal of the metal may be performed by wet-etching with using an etchant, which may be a mixture liquid of diluted sulfuric acid and hydrogen peroxide, an acid mixture containing phosphoric acid or ammonium persulfate, etc. Alternatively, it can be performed by dry-etching with using Cl₂ gas and Ar gas while maintaining a substrate at 200° C. or higher.

The depth of metal to be removed, measured from the upper surface of the insulating film 401, is in a range from 300 Å to 500 Å, for example, which is enough to obtain an etch stop function of an etch stop film 404b in the later step.

Then, as shown in FIG. 7c, an etch stop film 404a is formed on a whole surface of the wafer and then an excess portion of the etch stop film 404a left on the insulating film 401 is removed by CMP method, etc., as shown in FIG. 7d.

As the etch stop film 404a, an electrically conductive film of such as Ta, TaN, WN or TiN may be used, in lieu of a nitride film such as SiON or Si₃N₄, which is an insulating material and is usually used as an etch stop film. Such nitride film or electrically conductive film has a hydrogen blocking nature and, when it is formed on the whole surface of the insulating film 401, it becomes impossible to effectively perform the annealing with using forming gas.

Thereafter, an insulating film 405 is formed on the insulating film 401, as shown in FIG. 7e.

Then, contact plugs 407 are formed in the insulating film 405, for electrically connecting them to the metal wiring 403. In this case, when the etch stop film 404b is a nitride film of such as SiON or Si₃N₄, the contact plugs 407 are formed in the insulating film 405 and in the etch stop film 404b, as shown in FIG. 7f.

In the latter case, contact holes are formed in the insulating film 405 by using a patterned resist film (not shown) as a mask and the etch stop film 404b as an etch stop film. Then, the resist film (not shown) is removed by ashing it with using oxygen plasma. Further, the etch stop film 404b exposed in bottom portions of the contact holes is further etched with using the patterned insulating film 405 as a mask. In this manner, the contact holes directly connected to the metal wiring 403 are formed in the insulating film 405 and the etch stop film 404b. Thereafter, the contact plugs 407 are formed by filling the contact holes with metal.

When the etch stop film 404b is an electrically conductive film of such as Ta, TaN, WN or TiN, etc., the contact plugs 407 are electrically connected to the metal wiring 403 not directly but through the etch stop film 404b, as shown in FIG. 7g. However, in order to make the electrical connection more reliable, it is possible to directly connect the contact plugs 407 to the metal wiring 403 as in the case where the etch stop film 404b is the nitride film as shown in FIG. 7f. In the latter case, the connection is made in the same way as in the case where the nitride film is used as the etch stop film 404b.

When the electrically conductive film is used as the etch stop film 404b, it is possible to reduce the inter-wiring capacitance compared with the case where a low permittivity film such as nitride is used as the etch stop film to thereby fabricate a semiconductor device operable to higher speed.

(Second Modification of the Second Embodiment)

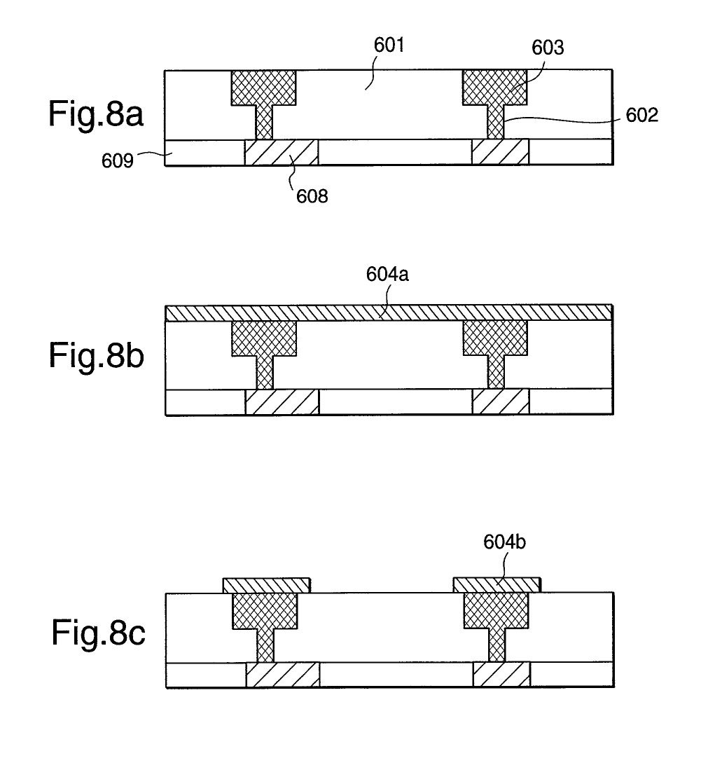

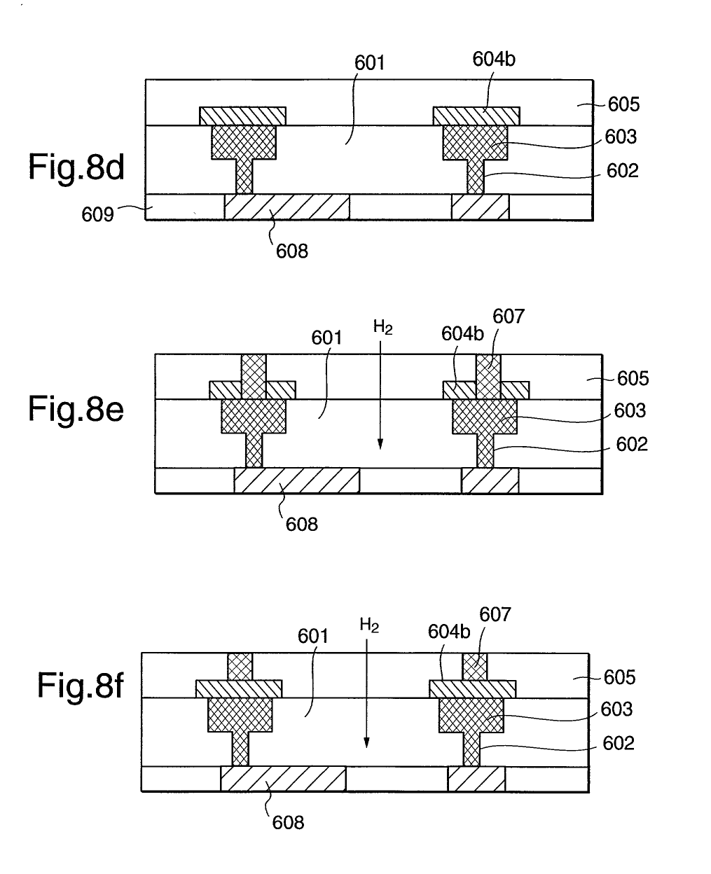

FIGS. 8a to 8f are cross sections showing fabrication steps of a semiconductor device having openings formed in an under-contact plug etch stop film underlying contact plugs formed on at least a metal wiring.

In FIG. 8a, metal wiring layers 603 and contact plugs 602 are formed by filling openings formed in an insulating film 601 with a metal material, as in the first embodiment of the second embodiment shown in FIG. 7a.

Then, as shown in FIG. 8b, an etch stop film 604a is formed on a whole surface of the insulating film 601. As the etch stop film 604a, an electrically conductive film of such as Ta, TaN, WN or TiN may be used, in lieu of a nitride film such as SiON or Si₃N₄, which is an insulating material and is usually used as an etch stop film.

Thereafter, as shown in FIG. 8c, the etch stop film 604a is patterned such that it is left on the metal wiring 603. The patterning can be performed by using usual photolithography technology.

The position, the pattern and the size of the etch stop film can be determined suitably, provided that it is provided as the etch stop film 604a on portions of the insulating film 601, which are exposed in bottom portion of contact holes formed in the insulating film 605, or in the vicinity of the portions. The etch stop film on other portions than the described portions are removed. That is, the portions of the etch stop film 604b, which function as the etch stop film in forming the contact holes in the insulating film 605 by etching, are left as they are. Further, the hydrogen diffusing passage is provided by leaving the etch stop film 604b also in the vicinity of those portions under consideration of the preciseness of the step, etc., and removing the etch stop film 604b on other portions.

Then, as shown in FIG. 8d, an insulating film 605 is formed on the insulating film 601.

Thereafter, contact plugs 607 are formed by filling the contact holes with metal and directly connected to the metal wiring 603 through the insulating film 605. As shown in FIG. 8e, when the etch stop film 604b is of a electrically non-conductive material, the contact holes are formed by etching with using a patterned resist film (not shown) as a mask and the etch stop film 604b as the etch stop film. Thereafter, the resist mask is removed by ashing it with using oxygen plasma. Then, the openings are formed by etching the etch stop film 604b exposed in the bottom portions of the openings with using the patterned insulating film 605 as a mask. The contact plugs 607 directly connected to the metal wiring 603 are formed in this manner.

In the first modification of the second embodiment, if, in FIG. 7f, the resist opening 408 is not precisely registered with a region on the metal wiring 403, a portion of the insulating film 401 is etched away in etching the insulating film 405 with using the resist mask (not shown) as a mask and side faces of the metal wiring 403 may be exposed. In such case, the exposed side faces are oxidized in the ashing step for removing the resist film, resulting in an increase of the wiring resistance. Contrary to this, in the second modification of the second embodiment, the above problem does not occur even when the resist opening is deviated from the region on the metal wiring 603 and the contact holes formed in the insulating film 605 deviate from that region, provided that the contact holes exist in at least the region on the etch stop film 604.

When the etch stop film 604b is an electrically conductive film of such as Ta, TaN, WN or TiN, etc., the contact plugs 607 are electrically connected to the metal wiring 603 not directly but through the etch stop film 604b, as shown in FIG. 8g. However, in order to make the electrical connection more reliable, it is possible to directly connect the contact plugs 607 to the metal wiring 603 as in the case where the etch stop film 604b is the nitride film as shown in FIG. 8e. In the latter case, the connection is made in the same way as in the case where the nitride film is used as the etch stop film 604b.

<Third Embodiment>

A semiconductor device according to the third embodiment, in which electrodes constituting semiconductor elements on a semiconductor substrate are electrically connected to a metal wiring, etc., on an upper insulating film through contact plugs provided in the insulating film and hydrogen can diffuse into interior of the semiconductor elements, will be described.

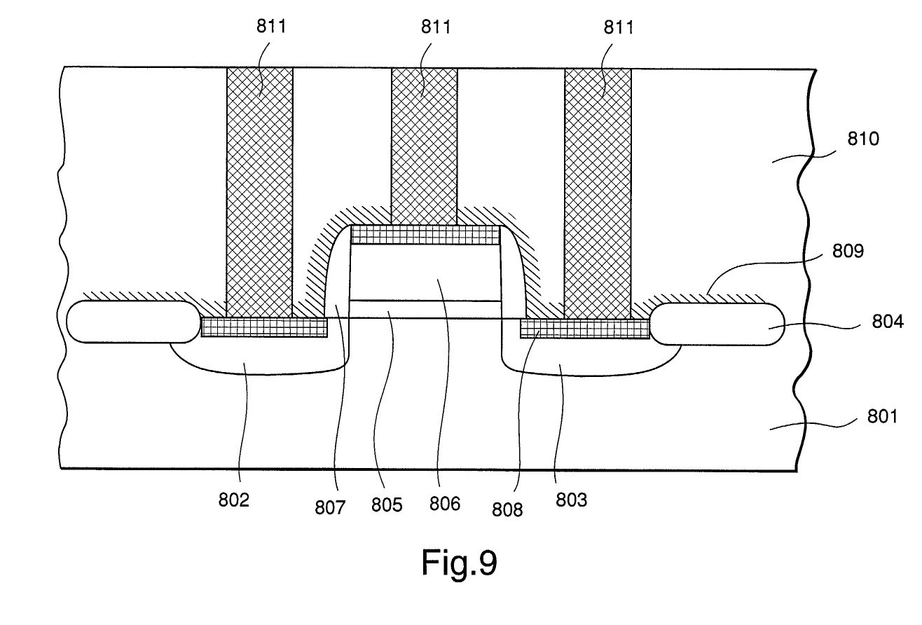

FIG. 9 shows the third embodiment . which includes a MOS FET type transistor formed on a semiconductor substrate. In FIG. 9, a source 802, a drain 803 and an element isolating film 804 separating the source from the drain are formed on the semiconductor substrate 801. Further, a gate electrode 806 is formed on the substrate 801 through a gate insulating film 805. On a side wall of the gate electrode 806, a sidewall 807.

An insulating film 810 is formed on these elements and contact plugs 811, which pass through the insulating film 810 up to the source 802, the drain 803 and the gate electrode 806, are formed. The source 802, the drain 803 or the gate electrode 806 is electrically connected to upper layers formed on the insulating film 810 through the contact plugs 811.

One of features of this embodiment is that silicide films 808 are formed in portions on the element side, at which the contact plugs 811 are connected to the elements and a Si₃N₄ film 809 having thickness in a range from 50 Å to 100 Å is further formed on the silicide film 808 and the sidewall 807, and that the contact plugs 811 pass through the Si₃N₄ film 809 and are connected to the silicide film 808 formed on the element side.

That is, the inventors of the present invention have found that the silicide film itself has etch stop function though the function is not so large as that of the Si₃N₄ film. That is, according to the present invention, the hydrogen diffusing passage is provided by forming the Si₃N₄ film having thickness much smaller than usual thickness and the etch stop function lost by the reduced thickness is recovered by forming the silicide film. Thus the etch stop function and the hydrogen diffusing ability are balanced in this manner. Though the hydrogen diffusing ability of the silicide film is not sufficient, hydrogen can diffuse through a region, on which not silicide film but nitride film is formed.

A nitride film is necessary for two reasons. Describing the first reason, it is difficult to precisely detect an end point of the etching for forming contact holes for the contact plugs 811 in the insulating film 810, so that over-etching tends to occur. Since, in such case, the regions of the source 802 and the drain 803 may be etched away, it is necessary to re-form the etched-away regions of the source 802 and the drain 803 by injecting ions into a surface of the semiconductor substrate 801 exposed in bottoms of the contact holes gain. The ion injection is performed by injecting ion of one conductivity type into both the source and drain regions and then injecting ion of the other conductivity type while masking one of the source and drain regions. That is, when the over-etching occurs, additional steps of ion injection and mask formation, etc., must be provided.

However, the etching of the insulating film 810 can be terminated precisely by providing the nitride film on the regions of the source 802 and the drain 803 and, therefore, it is possible to avoid the increase of fabrication step.

The second reason is that, when an area of the contact holes is larger than that of the regions of the source 802 and the drain 803 and overlaps on the gate electrode 806 or the element isolating film 804 partially, the sidewall 807 and/or the element isolating film 804 may be etched away. In order to prevent such phenomenon, a nitride film is formed on the source 802, the drain 803 and the gate electrode 806.

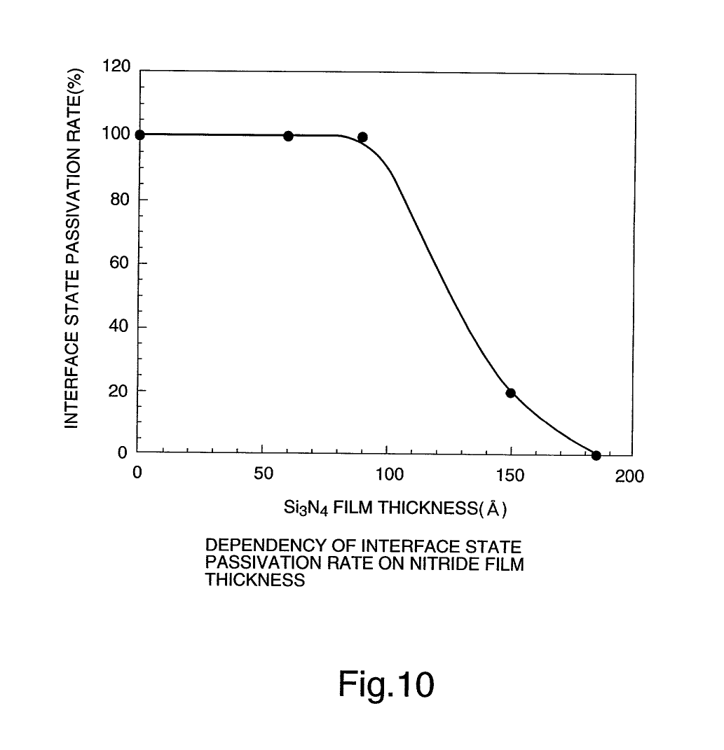

FIG. 10 shows a relation between thickness of the Si₃N₄ film formed by thermal CVD and interface state passivation rate, which has obtained by the present inventors. The term “interface state passivation rate” means percentage of interface state passivation when hydrogen barrier film exists, with interface state passivation when there is no hydrogen barrier film being 100%, and is related to hydrogen diffusion. For example, low interface state passivation rate means high hydrogen barrier function, that is, difficulty of hydrogen diffusion.

A Si₃N₄ film used usually has etching selectivity ratio in a range 7 to 10 for a silicon oxide film. Therefore, in order to satisfy the function of the etch stop film, the thickness of Si₃N₄ film must be 300 Å or more, preferably, 500 Å or more. In the MOS structure shown in FIG. 9, a difference in height between the gate electrode 806, which is usually a polysilicon film, and the regions of the source 802 and the drain 803 is 1500 Å. Therefore, the nitride film 809 functioning as an etch stop film is required in forming the contact plugs 811. When the Si₃N₄ film is used as the etch stop film, the thickness thereof is at least 150 Å and it is usually 500 Å.

In view of the hydrogen diffusion, however, it has been found that the blocking of hydrogen gas is started when the thickness of the Si₃N₄ film exceeds 100 Å and only about 20% of hydrogen can diffuse when the thickness is 150 Å and that, when the thickness thereof is 200 Å, hydrogen gas is substantially blocked and, when it is 500 Å, it does not diffuse.

As will be clear from FIG. 10, 90% or more of hydrogen diffusion effect can be obtained when the thickness of the Si₃N₄ film is 100 Å or less. Therefore, the object of the present invention can be achieved. It is preferable, considering the practical thickness, that the thickness of the Si₃N₄ film is in a range from 50 Å to 100 Å.

On the other hand, the thicker the silicide film provides the larger the etch stop function. Since the thickness of the silicide film influences the transistor characteristics, the thickness of the silicide film is arbitrarily determined by considering the transistor characteristics. The thickness of usual silicide film is in a range from 100 Å to 500 Å.

The silicide film is of, for example, cobalt silicide, titanium suicide or tungsten silicide.

<Fourth Embodiment>

The semiconductor devices, which are capable of diffusing hydrogen by using the metal wiring etch stop film, the contact plug etch stop film and the nitride film covering semiconductor elements according to the respective first, second and third embodiments, have been described. The fourth embodiment of the present invention relates to a combination of them.

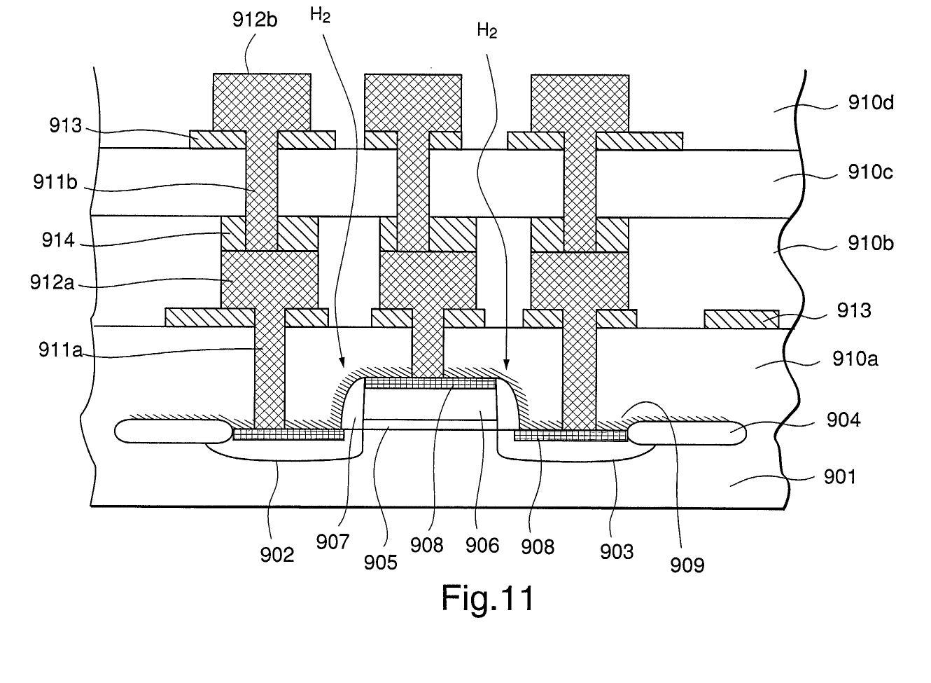

FIG. 11 is a cross section of a semiconductor device having a MOS FET type transistor on a semiconductor substrate according to the fourth embodiment, which can be annealed by using forming gas.

In FIG. 11, a source 902 and a drain 903 are formed in a region isolated by an element isolation film 904 on the semiconductor substrate 901. Further, a gate electrode 906 is formed on the substrate through a gate insulating film 905. A sidewall 907 is formed on a side wall of the gate electrode 906.

A first insulating film 910a is formed on these elements and contact plugs 911a are formed through the insulating film 910a. The source 902, the drain 903 or the gate electrode 906 is electrically connected to a metal wiring layer 912a in an upper layer formed on the first insulating film 910a through the contact plugs 911a.

Silicide films 908 are formed on respective portions, in which the contact plugs 911a are connected to the elements. In FIG. 11, the silicide films 908 are formed on the gate electrode 906 and on the source 902 and the drain 903. The silicide film 908 may be of cobalt silicide or titanium silicide, as mentioned previously.

Further, a Si₃N₄ film 909 having thickness in a range from 50 Å to 100 Å is formed on these elements and the contact plugs 911a penetrating the Si₃N₄ film 909 are connected to the silicide film 908 formed on the element side. This structure is similar to that of the semiconductor device capable of diffusing hydrogen into the semiconductor elements thereof and can be fabricated similarly.

A metal wiring 912a electrically connected the contact plugs 911a and a second insulating film 910b are formed in the order on the first insulating film 910a.

A hydrogen barrier film 913 is formed immediately below the metal as wiring 912a and above the first insulating film 910a and an opening, that is the hydrogen diffusing passage, is formed in other areas than the area of the hydrogen barrier film 913. This structure is similar to that of the semiconductor device of the second modification of the first embodiment and can be fabricated similarly.

The metal wiring 912a is buried in the second insulating film 910b by etching a surface of the metal wiring 912a down with respect to the upper surface of the second insulating film 910b and filling a space formed above the metal wiring 912a by this etching with an etch stop film 914.

Further, the contact plugs 911b pass through the etch stop film 914 and are connected to the metal wiring 912a. This structure is similar to that of the first modification of the second embodiment and can be fabricated similarly. In FIG. 11, the etch stop film 914 is of an electrically non-conductive material. However, the etch stop film 914 may be formed of an electrically conductive material.

In the case where the etch stop film 914 is formed of an electrically conductive material, it is possible to electrically contact the contact plugs to the metal wiring through the etch stop film.

Further, in FIG. 11, the metal wiring 912a is electrically connected to the metal wiring 912b through the contact plugs 911b passing through an insulating film 910c. In this case, it is also possible to provide a hydrogen diffusing passage by forming an opening in a metal wiring etch stop film 913.

As mentioned hereinbefore, in a semiconductor device having a multi-layer wiring structure, it is possible to provide the hydrogen diffusing passage throughout layers of the multi-layer wiring structure to thereby effectively perform an annealing processing using a forming gas.

According to the present invention, in a semiconductor device having a buried metal wiring structure and a contact structure passing through a film having a hydrogen barrier function for electrically connecting respective layers each other, an opening is formed in an etch stop film formed below the metal wiring, the etch stop film formed below contact plugs, except a portion thereof in the vicinity of connecting portions between the contact plugs and the metal wiring, is removed and a nitride film covering a surface of elements is made thinner than usual thickness of nitride film. Thus, it becomes possible to provide a hydrogen diffusing passage for allowing hydrogen contained in a forming gas to pass up to an interior of element, to thereby perform an effective annealing processing of the semiconductor device.

It is apparent that the present invention is not limited to the above mentioned embodiments, but may be modified and changed without departing from the scope and spirit of the invention.

What is claimed is:

1. A semiconductor device comprising:
a first insulating film covering semiconductor elements or a wiring formed on a semiconductor substrate;
at least one contact plug passing through said first insulating film and electrically connected to said semiconductor elements or said wiring;
a second insulating film formed on said first insulating film;
a metal wiring buried in said second insulating film and electrically connected to said contact plug; and
a film having hydrogen barrier function and formed in at least a region immediately below said metal wiring and between said metal wiring and said first insulating film, said film having hydrogen barrier function being formed with an opening in other region than said region to provide a hydrogen diffusing passage to layers below said second insulating film.

2. A semiconductor device as claimed in claim 1, wherein said film having hydrogen barrier function is a SiON film or a Si₃N₄ film.

3. A semiconductor device comprising:
a second insulating film formed on a first insulating film burying a metal wiring; and
at least one contact plug passing through said second insulating film and electrically connected to said metal wiring,
wherein said metal wiring formed in said first insulating film has an upper surface lower than an upper surface of said first insulating film to form a space above said upper surface of said metal wiring and a film having etch stop function is formed in only said space, wherein, when said film having etch stop function is an electrically non-conductive film, said contact plug passes through said film having etch stop function and is electrically connected to said metal wiring and, when said film having etch stop function is an electrically conductive film, said contact plug is electrically connected to said metal wiring through said film having etch stop function and wherein a hydrogen diffusing passage extending downwardly of said second insulating film is provided through other area than an area on which said metal wiring is formed.

4. A semiconductor device comprising:
a second insulating film formed on a first insulating film burying a metal wiring; and
at least one contact plug passing through said second insulating film and electrically connected to said metal wiring,
wherein a film having etch stop function is formed between said second insulating film and said metal wiring, wherein, when said film having etch stop function is an electrically non-conductive film, said contact plug passes through said film having etch stop function and is electrically connected to said metal wiring and, when said film having etch stop function is an electrically conductive film, said contact plug is electrically connected to said metal wiring through said film having etch stop function and wherein said film having etch stop function is removed except a portion thereof formed in the vicinity of connecting portions between said contact plug and said metal wiring to provide a hydrogen diffusing passage extending downwardly of said second insulating film.

5. A semiconductor device as claimed in any of claims 1 to 4, wherein said film having etch stop function is a SiON film or a Si₃N₄ film when said film having etch stop function is an electrically non-conductive film, and said film having etch stop function is of Ta, TaN, WN or TiN when said film having etch stop function is an electrically conductive film.

6. A semiconductor device as claimed in any of claims 1 to 5, wherein said metal wiring is of a material containing mainly copper, copper alloy, tungsten or aluminum.

7. A semiconductor device comprising:
at least one semiconductor element formed on a semiconductor substrate;
an insulating film covering said semiconductor element; and
at least a contact plug passing through said insulating film and electrically connected to at least one electrode of said semiconductor element;
wherein a silicide film is formed on a surface of said electrode and a Si₃N₄ film having thickness in a range from 50 Å to 100 Å is formed between said silicide film and said insulating film and wherein said contact plug passes through said Si₃N₄ film and is electrically connected to said silicide film.

8. A semiconductor device as claimed in claim 7, wherein said electrode is a polysilicon gate electrode, a source electrode or a drain electrode.

9. A semiconductor device as claimed in claim 8, wherein said silicide film is formed of cobalt silicide, titanium silicide or tungsten silicide.

10. A semiconductor device as claimed in any of claims 1 to 9, wherein said contact plug is formed on mainly tungsten, copper, copper alloy or aluminum.

11. A fabrication method for fabricating a semiconductor device including a first insulating film covering at least one semiconductor element or a wiring formed on a semiconductor substrate, at least one contact plug passing through said first insulating film and electrically connected to said semiconductor element or said wiring, a second insulating film formed on said first insulating film and a metal wiring buried in said second insulating film and electrically connected to said contact plug, said fabrication method comprising the steps of:
(a) forming a film having hydrogen barrier function on said first insulating film;
(b) patterning said film having hydrogen barrier function to form at least one via-hole for forming at least one contact hole and an opening functioning as a hydrogen diffusing passage in said film having hydrogen barrier function, while leaving a portion of said film having hydrogen barrier function, said portion functioning as an etch stop film in forming said metal wiring;
(c) forming a second insulating film on said patterned film having hydrogen barrier function on said first insulating film;
(d) forming, on said second insulating film, a resist pattern for forming wiring grooves for said metal wiring;
(e) simultaneously forming said wiring grooves and said contact hole by simultaneously etching said first and second insulating films with using said resist pattern as a mask, said film having hydrogen barrier function as an etch stop film for said wiring grooves and said via-hole as a mask opening of said contact hole; and
(f) forming said contact plug by filling said wiring grooves and said contact hole with a metal material after said resist film is removed.

12. A fabrication method for fabricating a semiconductor, as claimed in claim 11, wherein said film having hydrogen barrier function is a SiON film or a Si₃N₄ film.

13. A fabrication method for fabricating a semiconductor device including a second insulating film formed on a first insulating film burying a metal wiring and at least one contact plug passing through said second insulating film and electrically connected to said metal wiring, said fabrication method comprising the steps of:
(a) selectively etching said metal wiring buried in said first insulating film to remove an upper portion of said metal wiring in said first insulating film to provide a space on a selectively etched portion of said metal wiring;
(b) forming a film having etch stop function in only said space on said metal wiring;
(c) forming a second insulating film on said film having etch stop function on said first insulating film; and
(d) forming said contact plug such that said contact plug passes through said second insulating film and said film having etch stop function and is electrically connected to said metal wiring, when said film having etch stop function is an electrically non-conductive film, or forming said contact plug such that said contact plug passes through said second insulating film and is electrically connected to said metal wiring through said film having etch stop function, when said film having etch stop function is an electrically conductive film.

14. A fabrication method for fabricating a semiconductor device, as claimed in claim 13, wherein the step (b) includes the step of leaving said film having etch stop function in said space by using CMP method, after said film having etch stop function is formed on a whole surface of said first insulating film including said space on said metal wiring.

15. A fabrication method for fabricating a semiconductor device including a second insulating film formed on a first insulating film burying a metal wiring and at least one contact plug passing through said second insulating film and electrically connected to said metal wiring, said fabrication method comprising the steps of:
(a) forming a film having etch stop function on said first insulating film and said metal wiring buried in said first insulating film;
(b) etching said film having etch stop function to leave a portion thereof functioning as an etch stop film in forming said contact plug in a later step;
(c) forming a second insulating film on said film having etch stop function and said first insulating film; and
(d) forming said contact plug such that said contact plug passes through said second insulating film and said film having etch stop function and is electrically connected to said metal wiring, when said etch stop film is an electrically non-conductive film, or forming said contact plug such that said contact plug passes through said second insulating film and is electrically connected to said metal wiring through said film having etch stop function, when said film having etch stop function is an electrically conductive film.

16. A fabrication method for fabricating a semiconductor device, as claimed in any of claims 13 to 15, wherein said film having etch stop function is an electrically non-conductive film including a SiON film or a Si₃N₄ film or an electrically conductive film formed of Ta, TaN, WN or TiN.

17. A semiconductor device as claimed in any of claims 1 to 16, wherein said contact plug contains tungsten, copper, copper alloy or aluminum, mainly.

18. A semiconductor device as claimed in any of claims 11 to 17, wherein said metal wiring contains tungsten, copper, copper alloy or aluminum, mainly.
